(19) United States
(12) Patent Application Publication
(10) Pub. No.: US 2002/0171436 A1
(43) Pub. Date: Nov. 21, 2002

(54) Device for connecting parallel sources of electric power at a meter socket

(75) Inventor: Miles C. Russell, Lincoln, MA (US)

Correspondence Address: Pandiscio & Pandiscio, 470 Totten Pond Road, Waltham, MA, 02451, US

(73) Assignee: Schott Applied Power Corporation

(21) Appl. No.: 10/146,313

(22) Filed: May 15, 2002

Related U.S. Application Data
(60) Provisional application No. 60/292,279, filed on May 21, 2001.

(51) Int. Cl. G01R 27/02

(52) U.S. Cl. 324/602

(57) ABSTRACT

Apparatus for coupling an auxiliary ac power source to electrical circuits in parallel with a primary ac power source comprises a “meter extender” that is adapted for installation installed between a kilowatt-hour meter and socket for the meter. The meter extender comprises contact terminals on one side that mate with contact terminals forming part of the meter socket and additional contact terminals on a second side that mate with contact terminals forming part of the meter.

This application claims the benefit of the priority date of U.S. Provisional Patent Application No. 60/292,279, filed May 21, 2001 for “Device For Connecting Parallel Sources Of Electric Power At A Meter Socket”.

### INTRODUCTION

This invention relates to electric power coupling and metering and more particularly to an apparatus for connecting an auxiliary source of electrical power, such as a photovoltaic system, in parallel with a primary power supply at the socket of a kilowatt-hour meter.

### BACKGROUND OF THE INVENTION

The market for sources of electric power that can operate in parallel with an existing grid electricity supply and that can be safely and simply installed in homes, businesses, factories, schools, hospitals, commercial establishments and the like, is growing rapidly in many countries. Examples of such auxiliary sources of electric power include solar photovoltaic (solar electric) power systems, wind machines, fuel cells and the like. There exists a need for means for easily coupling such auxiliary power sources to the wired circuits of buildings and other premises that normally receive their electricity from a public utility service or some other primary power supply. Kilowatt-hour meters are permanently installed on customer premises by the grid electricity provider to record the usage of grid electricity for billing purposes. In this connection it is to be appreciated that the power received from an auxiliary power source not only reduces the amount of power required to be supplied from the primary source but also can be fed back into the public service grid to the extent that it is not used by the wired premises. Accordingly, it is desirable to connect the auxiliary power supply to the kilowatt-hour meter of the wired premises so that the meter can operate to reduce the recorded usage of primary power by the amount of electric power supplied by the auxiliary power source that is fed back to the primary power source.

### OBJECTS AND SUMMARY OF THE INVENTION

The primary object of this invention is to provide a means for easily and reliably coupling an auxiliary power supply in parallel with a primary power supply, with the coupling being achieved via a kilowatt-hour meter unit of a wired installation.

Another object is to provide a device for connecting parallel sources of electric power at a meter socket.

A further object is to provide a device for connecting an auxiliary source of electric power to wired circuits of a building or other premises in parallel with a primary power supply and in series with a watt-hour meter that monitors power consumption by the wired circuits, with the device comprising overcurrent protection coupled to the conductors leading to the auxiliary power source.

These and other objects of the invention are achieved by providing a “meter extender” (i.e., a meter interconnect device or apparatus) for use with an electrical power measuring unit of the type comprising a meter socket that is adapted for electrical connection to the wired circuits of a building or other premises and also to the primary power supply for the wired circuits, and a kilowatt-hour meter that is adapted to make a plug and socket connection with the meter socket. The meter extender is installed between a kilowatt-hour meter socket and the associated kilowatt-hour meter, with the meter extender comprising a plurality of contacts on one side thereof that are adapted to make a plug-and-socket type connection with the meter socket and a second plurality of contacts on the opposite side thereof are adapted to make a plug-and-socket type connection with the meter. Certain of the contacts carried by the meter extender serve to couple the meter to meter socket terminals that are to be connected to the utility service and others of the contacts carried by the meter extender serve to couple the meter to meter socket terminals that are to be connected to the wired circuits (directly or via a distribution panel), with said other contacts of the meter extender also being pre-wired for connection to an auxiliary power source so as to couple the auxiliary power source to the wired circuits in parallel with the utility service. In the preferred embodiment of the invention, the meter extender also includes overcurrent protection for the conductors used to couple the auxiliary power supply to the wired circuits, with the overcurrent protection being in the form of fuses. Preferably the meter extender device is connected to the auxiliary power supply via a pre-wired, manually-operated, lockable disconnect switch, whereby the parallel auxiliary power source may be isolated from the primary power supply and the wired circuits.

Other features and advantages, as well as other objects of the invention, are described in or rendered obvious by the following detailed specification which is to be considered together with the accompanying drawings.

### THE DRAWINGS

FIG. 1 schematically illustrates the invention;

FIG. 2 is a front elevation of a meter interconnect device constituting a preferred form of the invention attached to a meter socket box;

FIG. 3 is an exploded view in front elevation of the apparatus shown in FIG. 2;

FIG. 3A is an enlargement of a portion of FIG. 3;

FIG. 4 is an exploded view in rear elevation of the same apparatus;

FIG. 5 is a side view in elevation showing the interconnect device disposed between and connecting a watt-hour meter to the meter socket box;

FIG. 6 is an exploded view in side elevation of the apparatus shown in FIG. 5; and

FIG. 7 is a schematic drawing illustrating a typical application for the invention;

In the several figures, like parts are identified by like numerals.

### DETAILED DESCRIPTION OF THE INVENTION

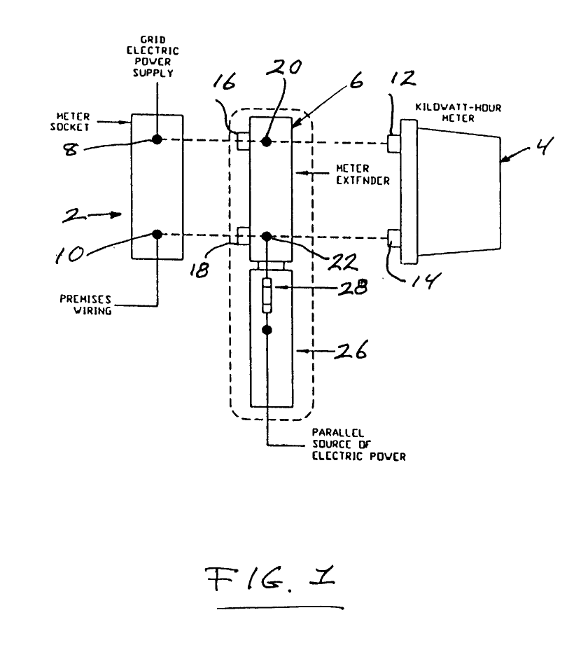

FIG. 1 schematically illustrates a meter “socket” or receptacle 2, a kilowatt-hour meter 4, and a meter extender 6 incorporating the present invention. Meter socket 2 and meter 4 are of conventional construction, with the meter socket comprising a case or housing (not shown) that encloses and supports terminal contacts 8 and 10 that mate with other terminal contacts 12 and 14 carried by the meter. Typically, the contact portions of terminal contacts 8 and 10 are female-type and are in the form of spring-like jaws and the contact portions of terminal contacts 12 and 14 are male-type and are in the form of blades that are sized to fit within and intimately engage the spring-like jaws. Although not shown in FIG. 1, the typical socket comprises two terminal contacts 8 and two terminal contacts 10 laid out in standardized patterns called “forms”, and similarly the meter has two terminal contacts 12 and two terminal contacts 14 arranged in the same pattern.

The terminal portions of terminal contacts 8 are connected to a primary source of electrical ac power such as a grid electric power supply at 240 volts, while the terminal portions of terminal contacts 10 are connected to wired electricity use circuits, such as the premises wiring of a building. The socket housing also includes means (not shown) for establishing an electrical ground so that, if the primary power supply is at 240 volts, each of the terminal contacts 8 will have a potential of 120 volts. When the meter is attached to its socket, electricity from a connected primary power supply will pass to the meter via terminal contacts 8 and 12, and then passes from the meter to the premises wiring or other electricity use circuits via terminal contacts 14 and 10.

Conventional watt-hour meters and their companion sockets may take various forms, as exemplified by U.S. Pat. No. 2,105,396, issued Jan. 11, 1938 to H. A. Bakke; U.S. Pat. No. 2,115,429, issued Apr. 26, 1938 to A. B. Rypinski; U.S. Pat. No. 2,643,362, issued Jun. 23, 1953 to E. G. Johansson; U.S. Pat. No. 3,519,976, issued Jul. 7, 1970 to H. J. Orr; U.S. Pat. No. 3,528,049, issued Sep. 8, 1970 to H. J. Orr; and U.S. Pat. No. 5,571,024, issued Nov. 5, 1996 to V. J. Ranoia.

The meter extender 6 comprises terminal contacts 16 and 18 on one side for making connections to terminal contacts of meter socket 2 and additional terminal contacts 20 and 22 for making connections to terminal contacts 12 and 14 of the meter. Although not shown in FIG. 1, it is to be understood that the meter extender comprises two each of terminal contacts 16, 18, 20 and 22 laid out in the same standardized pattern as contacts 8, 10, 20 and 22. The invention also includes other means, notably, overcurrent protection means 28 and wiring terminals contained in an associated enclosure 26.

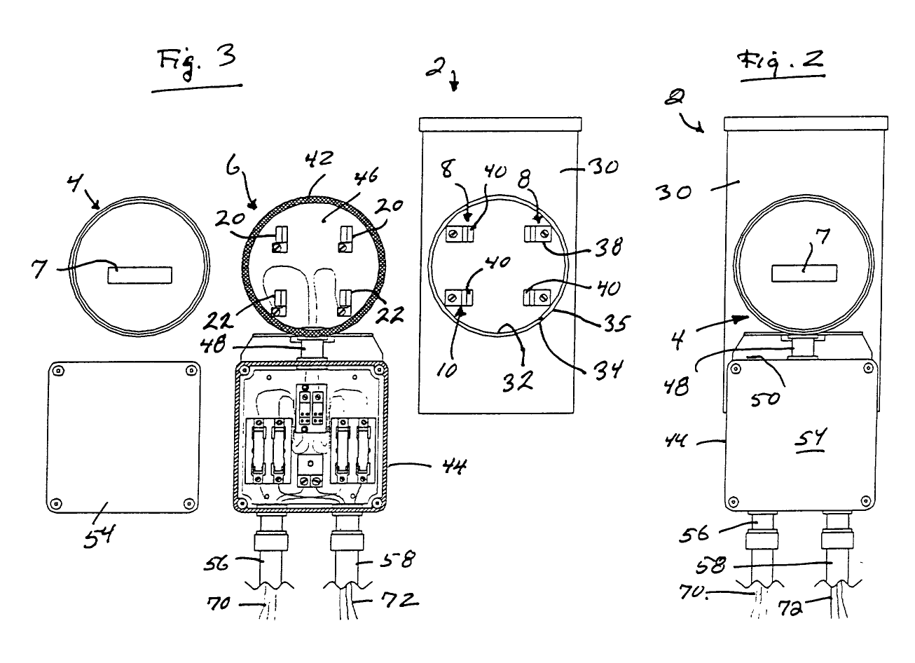

Referring now to FIGS. 2-7, according to the preferred embodiment of the invention, a conventional meter socket 2 includes a terminal box 30 having a circular aperture 32 on its front side. A forwardly extending flange 34 surrounds aperture 32. Box 30 is intended to be mounted to a building wall or other suitable support. Mounted within box 30 are first and second pairs of like terminal contacts 8 and 10 that have their terminal portions 38 secured to but insulated from the box. The contact portions 40 of terminal contacts 8 and 10 are in the form of spring-like jaws. Box 30 has openings (not illustrated) in its top, side and/or rear walls through which cables (not shown) leading to a primary power supply and also to a distribution panel of a building or other facility may be connected to the terminal portions of terminal contacts 8 and 10. To the extent described, the meter socket 2 is of conventional construction.

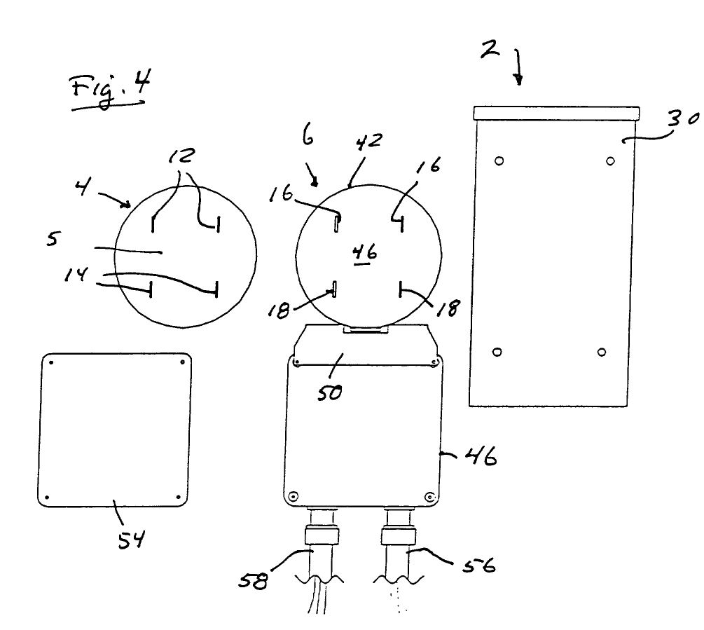

Still referring to FIGS. 2-6, the meter extender unit 6 comprises a cylindrical top housing 42 and a secondary housing 44. The circular housing 42 comprises a wall or partition 46 that serves as a support for two pairs of like blade-type terminal contacts 16 and 18 (FIGS. 4-6) that project rearwardly of the housing. The front side of the partition 46 serves as a support for two pairs of like jaw-type terminal contacts 20 and 22. Unless partition 46 is made of a non-conductive material, terminal contacts 16, 18, 20 and 22 are electrically insulated from the partition. Each terminal contact 20 is aligned with and electrically coupled through partition 46 to the adjacent contact 16. Similarly, each terminal contact 22 is aligned with and electrically coupled through partition 46 to the adjacent terminal contact 18 on the opposite side of the partition.

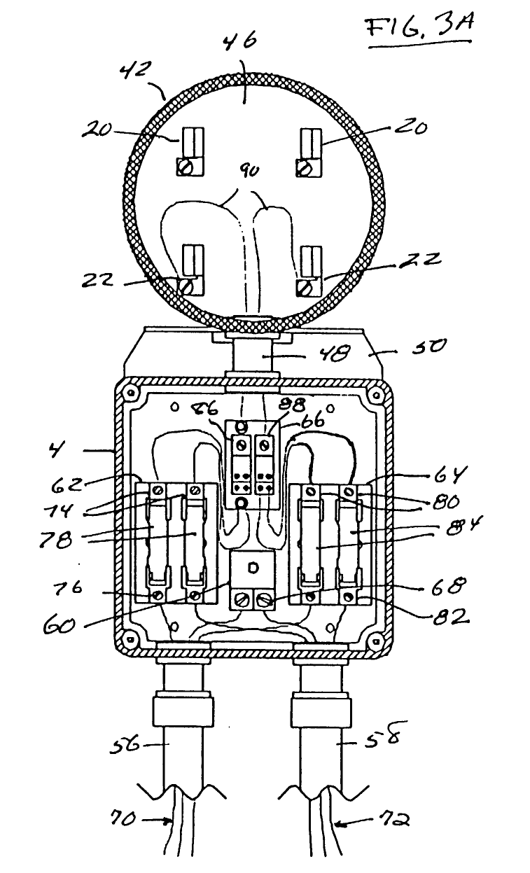

In the illustrated embodiment, housing 44 is attached to upper housing 42 by a short conduit 48 and a supporting connector plate 50. Plate 50 may be connected to housings 42 and 44 in any convenient way, e.g. by screw fasteners. Conduit 48 communicates with the interiors of housings 42 and 44 and functions as a passageway for connecting wire conductors. Housing 44 includes a removable cover plate 54 that is held in place by screws. Removal of the cover plate, as shown in FIGS. 3 and 3A, exposes the contents of box 44. In this case the housing 44 is provided with means for coupling two auxiliary power sources in parallel with the grid power supply. Thus two conduits 56 and 58 are attached to openings in housing 44, with the conduits serving as passageways for two power cables, identified generally at 70 and 72, that lead to separate auxiliary power supplies. In the illustrated embodiment, power cables 70 and 72 each has three wires, one ground and two live. To provide the desired connections, housing 44 is provided with a ground lug block 60, two fuse terminal blocks 62 and 64, and a power block 66 (FIG. 3A). Ground lug block 60 has a conductive terminal strip with screws 68 for attachment of the ground wires from power cables 70 and 72.

Fuse terminal block 62 comprises two pairs of fuse holders 74 and 76 for holding fuses 78 between them. Fuse terminal block 64 comprises two pairs of like fuse holders 80 and 82 for holding fuses 84 between them. The power block fuses provide overcurrent protection. One of the two live wires of power cable 70 is connected to a fuse holder 76 and the other of its live wires is connected to a fuse holder 82. One of the two live wires of power cable 72 is connected to the other fuse holder 76 and the other live wire of that same cable is connected to the other fuse holder 82.

Power block 66 comprises two conductive terminal strips 86 and 88. As seen best in FIG. 3A, the two fuse holders 74 are connected by conductive wires to terminal strip 86, while the two fuse holders 80 are connected by wires to terminal strip 88. Also electrically conductive wires 90 are used to connect terminal strip 86 to one of the contacts 22 and terminal strip 88 to the other terminal contact 22.

Referring now to FIGS. 4-6, meter 4 is of conventional construction and is provided with blade terminals 12 and 14 which project from its rear side and plug into the contacts 20 and 22 respectively, so as to provide a circuit arrangement as illustrated in FIG. 1. The front side of meter 4 provides a watt-hour display as represented schematically at 7. Preferably, but not necessarily, the rear side of meter 4 has a projecting portion 92 that is sized to make a close fit within meter extender housing 42. Similarly, the rear side of the housing 42 has a projecting portion 94 that is sized to make a snug fit within the circular flange 34 of box 30.

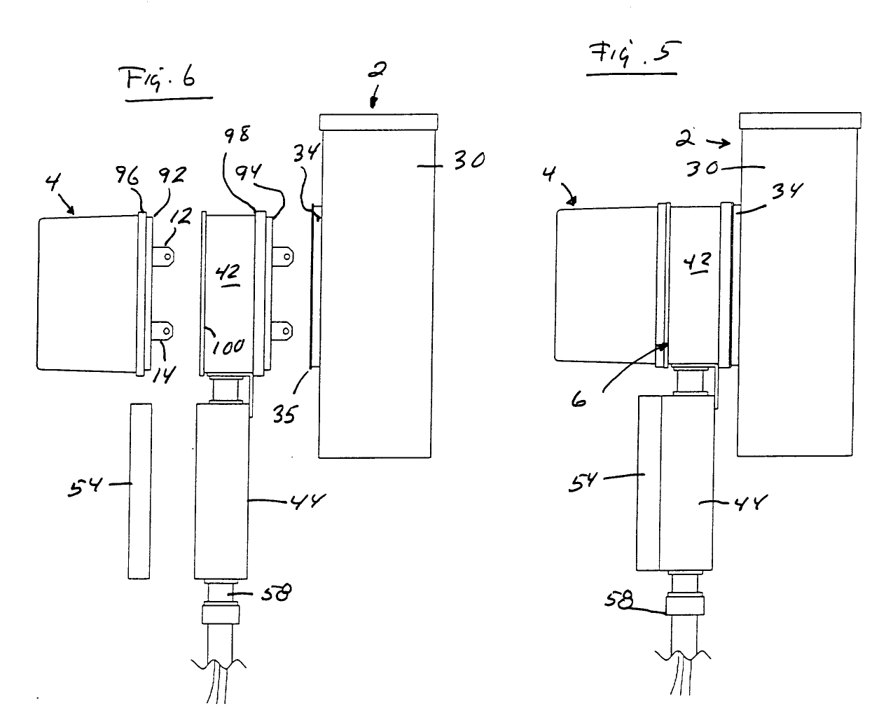

In customary practice, the watt-hour meter is locked to the meter socket by the utility service to prevent tampering. Typically this is accomplished by providing the flange 34 with a radially and outwardly projecting lip as shown at 35 (FIG. 6) and also providing the meter housing with a peripheral rib as shown at 96, with a lock ring (not shown) placed around the flange 34 and the rear end of the meter housing in mechanical interlocking relation with lip 35 and rib 96. In keeping with that practice, the extender housing is formed with circumferential ribs 98 and 100 (FIG. 6) at its rear and front ends. Then one lock ring (not shown) may be applied over flange 34 and rib 35 and rib 98 to lock extender housing 42 to meter socket box 30, and another lock ring (also not shown) may be applied around extender housing rib 100 and meter rib 96 to lock extender housing 42 to the meter housing, with the result that the meter extender is mechanically fixed to and electrically coupled with both meter socket 2 and meter 4. The form of the lock rings is not critical and take various shapes, e.g., the meter lock ring 11 illustrated in U.S. Pat. No. 2,115,429, issued Apr. 26, 1938 to A. B. Rypinski or the lock ring disclosed by FIG. 1 of U.S. Pat. No. 1,969,499 issued to Bradshaw et al.

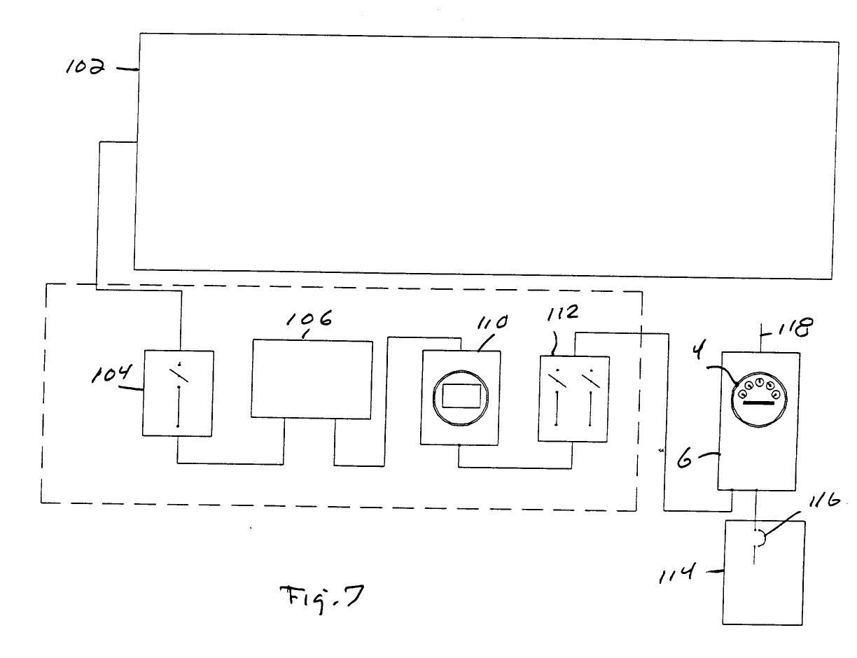

FIG. 7 illustrates one form of auxiliary power source installation which may be coupled to the wired circuits of a building or other facility by means of the present invention. The system shown in FIG. 7 comprises a conventional photovoltaic array 102 made up of a plurality of interconnected solar cell panels (not shown) that coact to produce a dc output current in response to received solar energy. The construction of the solar array and its solar cell panels may take various forms without affecting the present invention. The output of the array is coupled by a lockable dc switch 104 to an inverter 106 that converts the dc current to ac current, typically at a level of 240 volts ac. The output of inverter 106 is applied to a watt meter 110 which measures the ac power level. A lockable ac switch 112 coupled to meter 110 controls transfer and application of ac power derived from the auxiliary power source to the electrical circuits of a building or other facility via meter extender 6 and meter 4. In FIG. 7, the block 114 represent a distribution panel of a building which typically includes a main circuit breaker 116, and the line 118 represents the connection to the primary power supply, e.g., an electric utility service.

With an arrangement as shown in FIGS. 1-7, the auxiliary power supply is connected in parallel with the meter and the wired premises represented by distribution panel 114 and with the primary power supply. Ac power derived from the photovoltaic array 102 is available to power the wired premises simultaneously with power from the primary power supply. If the primary power supply is on line but the circuits of the wired premises are not calling for power or less power than is available from the auxiliary power supply, then ac power from the auxiliary power supply will be fed automatically back to the primary power supply via meter 4 and, because of the direction of that current flow, the meter will run backwards to reduce its reading by the amount of energy fed back to the utility service grid.

The invention is susceptible of modifications. For one thing, the meter extender the two housings 42 and 44 may be combined into a single housing that includes front and back portions that are adapted to mate with the meter and the meter socket in a manner that provides the required mechanical and electrical connections to achieve the mode of operation describe above. The invention also may be used with socket terminal boxes that have a cylindrical rather than a box-like configuration. Also although the jaw-like contacts are on the socket and the blade-like contacts are on the meter, it is realized that a reverse arrangement may be possible. In such case, the blade-like terminals and jaw-like terminals of the extender would be reversed to mate with the meter and socket terminals. The meter extender also may be modified for use with meters and meter sockets that utilize other forms of terminal contacts and other means of locking the meters and meter sockets together. It is contemplated also that a pre-wired, integrated, manually-operated, lockable disconnect switch may be installed in the extender housing 44 to permit the user to isolate the auxiliary source of electrical power from the grid electric supply and the premises wiring. The operating button or handle for such a disconnect switch could be located either inside or outside of the housing.

The meter extender may be modified further by including sensors and associated equipment to monitor and electronically log performance data from the parallel source of electric power, a visual display indicating the power and energy performance of the parallel source of electric power, and communication means for transfer such information via wired and wireless communications protocols, including the internet. The communications protocol can also be used for control purposes such as enabling and disconnecting the parallel source. The meter extender could also have an interface with a building energy control system. Still other modifications will be obvious to persons skilled in the art from the foregoing description.

In addition to being susceptible of different modifications, the invention offers other advantages. The meter extender is simple to construct and install and makes use of conventional watt-hour meter constructions. It also may be used to connect various forms of auxiliary power supplies in parallel with a grid supply. As described and illustrated herein, the invention allows the conductors from the parallel source of electric power to be pre-wired to connect to the premises-wiring side of the meter socket, resulting in a so-called “net metering” arrangement. Alternatively, those conductors can be pre-wired to connect to the grid electric supply side of the meter socket. In its preferred form the invention is applicable to 120/240 Volt ac service, typical of residential electric service in the United States. However, it is adaptable to use with 3-phase 120/208 Volt ac service, and 480/277 volt ac service found in certain non-residential electric service installation in the United States. The invention also may be adapted to various other voltages used internationally. Still other advantages will be obvious to persons skilled in the art from the foregoing description and the drawings.

As used herein the term “meter socket” means and includes a box or case that includes contact terminals to which grid electric service conductors are connected and contact terminals to which premises wiring conductors are connected. Additionally, those contact terminals are adapted to mate with contacts on a removable watt-hour meter that is attached to the meter socket.

As used herein, the term “building” is intended to embrace various forms of buildings and other structures that house or contain electrical use circuits (i.e., circuits that consume electricity or deliver electricity to electrically powered or consuming devices such as, for example, lamps, electric motors, heaters, and air conditioning equipment).

What is claimed is:

1. Electrical apparatus comprising:
a meter receptacle adapted to be mounted to a building and comprising first electrically conductive contact means adapted for connection to a grid electrical power supply and second electrically conductive contact means adapted for connection to an electrical circuit associated with said building;
a kilowatt-hour meter having third and fourth electrically conductive contact means on a rear side thereof; and
a meter extender having first and second opposite sides, fifth and sixth electrically conductive contact means on said first side, and seventh and eighth electrically conductive contact means on said opposite side, said fifth and sixth electrically conductive contact means being connected to said seventh and eighth electrically conductive contact means respectively, said fifth and sixth electrically conductive contact mean being adapted for engagement with said first and second electrically conductive contact means respectively when said meter extender is attached to said meter receptacle with said first side facing said meter receptacle, and said seventh and eighth electrically conductive contact means being adapted for engagement with said third and fourth electrically conductive contact means respectively when said meter is attached to said second side of said extender with said rear side thereof facing said extender, and said eighth electrically conductive contact means being adapted for connection to an auxiliary electrical power supply, whereby an auxiliary electrical power supply connected to said eighth electrically conductive contact means may be coupled to said meter in parallel with a grid electrical power supply that is connected to said first electrically conductive contact means when said meter extender is attached to said meter receptacle and said meter is attached to said meter extender.

2. Electrical apparatus according to claim 1 wherein said meter receptacle comprises a box with a support for said first and second electrically conductive contact means, said box having an opening through which said first and second contact means are accessible, and further wherein said extender comprises a housing having means for supporting said fifth, sixth, seventh and eighth electrically conductive contact means, said housing being adapted for attachment to said box so that said fifth, sixth, seventh and eighth electrically conductive contact means are aligned with said opening.

3. Electrical apparatus according to claim 2 further including connection means attached to said housing for connecting said eighth electrically conductive contact means to an auxiliary electrical power supply.

4. Electrical apparatus according to claim 3 wherein said connection means includes current protection means.

5. Electrical apparatus according to claim 4 wherein said current protection means comprises fuses.

6. Electrical apparatus comprising:
a meter socket (2) adapted to be mounted to a building and comprising a first set of electrically conductive contacts (8) adapted for connection to a primary source of electrical power and a second set of electrically conductive contacts (10) adapted for connection to an electrical circuit associated with said building;
a kilowatt-hour meter (4) having a base plate and third (12) and fourth (14) sets of electrically conductive contacts on said base plate adapted for mating engagement with said first and second sets of electrically conductive contacts respectively; and
a meter extender having first and second opposite sides, fifth (16) and sixth (18) sets of electrically conductive contacts on said first side adapted for engagement with said first (8) and second (10) sets of electrically conductive contacts respectively when said meter extender is attached to said meter socket (2) with said first side facing said meter socket, and seventh (20) and eighth (22) sets of electrically conductive contacts on said second side adapted for engagement with said third (12) and fourth (14) sets of electrically conductive contacts respectively when said meter is attached to said second side of said extender with said base plate facing said extender, said fifth (16) and sixth (18) sets of electrical electrically conductive contacts being electrically connected to said seventh (20) and eighth (22) electrically conductive contacts respectively, and said eighth (22) set of electrically conductive contacts being adapted for connection to another source of electrical power, whereby said another source of electrical power may be coupled to said meter in parallel with a primary source of electrical power that is connected to said first contacts (8) when said extender is attached to said receptacle and said meter is attached to said extender.

7. Apparatus according to claim 6 wherein said first, second, seventh and eighth sets of electrically conductive contacts (8, 10, 20 and 22) are in the form of jaws and said third, fourth, fifth and sixth sets of jaws (12, 14, 16 and 18) are in the form of blades that are sized to make a close fit in said jaws.

8. Apparatus according to claim 6 wherein said meter extender includes connector means (90, 66, 62, 64) for connecting said eighth set of electrically conductive contacts to said another source of electrical power.

9. Apparatus according to claim 8 wherein said connector means includes current protection means (78, 84).

10. Electrical apparatus for use in connecting an auxiliary electrical power supply to a kilowatt hour meter unit in parallel with an existing grid electrical power supply, said kilowatt hour meter unit comprising a meter receptacle having a first set of electrically conductive contacts adapted for connection to a grid electrical power supply and a second set of electrically conductive contacts adapted for connection to an electrical power-consuming circuit, and a kilowatt-hour meter comprising a meter case and third and fourth sets of electrical electrically conductive contacts adapted for mating engagement with said first and second sets of contacts, said apparatus comprising:
a housing adapted for positioning between and attachment to said receptacle and said meter case, said housing containing on one side thereof fifth and sixth sets of electrical electrically conductive contacts that are positioned and adapted for mating engagement with said first and second sets of contacts, said housing also containing on an opposite side thereof seventh and eighth sets of electrical electrically conductive contacts that are positioned and adapted for engagement with said third and fourth sets of electrical contacts, and means for connecting said eighth set of electrically conductive contacts to an auxiliary electrical power supply, whereby when said meter is connected to said receptacle via said apparatus so that said fifth and sixth sets of electrically conductive contacts are engaged with said first and second sets of electrically conductive contacts respectively and said third and fourth sets of electrically conductive contacts are engaged with said seventh and eighth sets of electrically conductive contacts respectively, said auxiliary power supply will be coupled to said meter in parallel with any grid electrical power supply that is connected to said first set of contacts.

11. Electrical power supply apparatus comprising:
an auxiliary ac power supply;
a kilowatt-hour meter unit comprising a meter receptacle attached to a building and a kilowatt-hour meter, said meter receptacle comprising a first housing containing a first set of electrical contacts connected to an electrical circuit associated with said building and a second set of electrical contacts connected to a primary ac power supply, and said meter comprising a case supporting a third set of electrical contacts through which electrical power is applied to said meter and a fourth set of electrical contacts through which electrical power passes out of said meter; and
a meter extender comprising a second housing having a rear side and a front side, with said rear side being attached to said first housing and said meter being attached to said front side, said second housing having fifth and sixth sets of electrical contacts projecting from said rear side and engaged with said first and second sets of electrical contacts respectively; said second housing also having seventh and eighth sets of electrical contacts projecting from said front side of said second housing and engaged with said third and fourth sets of electrical contacts respectively, and means connecting said auxiliary power supply to said fifth or sixth set of electrical contacts in parallel with said primary power supply.

12. Electrical power supply apparatus according to claim 11 wherein said auxiliary power supply apparatus comprises a photovoltaic current generator for generating a dc current, an inverter for converting said dc current to ac current, and switch means connected between said inverter and said fifth or sixth set of electrical contacts for means for controlling delivery of said ac current to said fifth or sixth set of electrical contacts.

13. Electrical power supply apparatus according to claim 12 wherein said first, second, seventh and eighth sets of electrical contacts are female contacts and said third, fourth, fifth and sixth sets of electrical contacts are male contacts.

14. Electrical power supply apparatus according to claim 13 wherein said female contacts are in the form of spring jaws and said male contacts are in the form of blades that are sized to make a close fit in said jaws.

15. Electrical power supply apparatus comprising:
a primary ac power supply;
an electrical use circuit;
an auxiliary ac power supply;
a plug-in kilowatt-hour meter unit comprising a meter socket connected between to said primary power supply and said use circuit, and a kilowatt-hour meter that is adapted to plug into said socket and has means, operative when said meter is plugged into said socket, for measuring the ac electrical power delivered from said primary power supply to said use circuit; and
a meter extender interposed between said meter socket and said meter, said meter extender comprising means electrically coupling said meter to said socket and means for electrically connecting said auxiliary ac power supply to said meter in parallel to said primary power supply.

16. Electrical power supply apparatus according to claim 15 wherein said auxiliary power supply comprises (a) means for generating electricity from solar energy or wind energy, or (b) a fuel cell.

17. Electrical power supply apparatus according to claim 15 wherein said meter extender comprises current protection means connected between and in series with said auxiliary power supply and said meter.
